(19) United States
(12) Patent Application Publication
(10) Pub. No.: US 2003/0009301 A1
(43) Pub. Date: Jan. 9, 2003

(54) Integrated utility meter-reading, billing, payment and usage management system

(76) Inventors: M.B. Anand, Germantown, MD (US); Prakash Chakravarthi, Gaithersburg, MD (US)

Correspondence Address: J.W. Gipple, P.O. Box 40513, Washington, DC, 20016, US

(21) Appl. No.: 10/210,050

(22) Filed: Aug. 2, 2002

Related U.S. Application Data
(63) Continuation-in-part of application No. 09/579,234, filed on May 30, 2000.

(51) Int. Cl. G06F 19/00; G01R 21/00; G01R 21/06

(52) U.S. Cl. 702/62

(57) ABSTRACT

An automatic, integrated utility usage monitoring, management, billing and payment system is described. Meter reading devices are spread over a geographical area and transmit usage data to a control device which communicates such data to a service device by means of a global communications network.

This invention is a continuation-in-part of application Ser. No. 09/579,234, filed May 30, 2000, with certain improvements described herein.

### BACKGROUND OF THE INVENTION

1. Field of the Invention

This invention relates, in general, to automatic remote communication systems and, in particular, to an automatic, integrated Utility usage monitoring, management, billing and payment system.

2. Description of the Prior Art

The provision of utilities such as electricity, gas and water to consumers obviously requires regular monitoring of the usage. This function is usually performed by means of a meter installed at the point of usage. The consumer is then billed for the usage of the Utility based on readings of the meter at periodic intervals and subsequently pays the company providing Utility for the usage. The act of reading the meter and recording the usage has traditionally been performed manually by meter readers visiting each individual meter installation at periodic intervals. The Utility company then mails out a bill to the consumer, who subsequently pays the Utility company by, for example, mailing a check. The Utility company collects this payment, thus completing one billing cycle. It is thus seen that four distinct events are involved in this cycle in the following sequence: a) reading the meter (to be performed by the Utility company), b) sending out a bill (to be performed by the Utility company), c) paying the bill (to be performed by the consumer) and d) collecting the payment (to be performed by the Utility company). This sequence is repeated every billing period, which may, for example, be one month.

It is immediately obvious that significant advantages could be gained by the automation of the events involved in this sequence:

1) For the Utility company, the requirement of sending out a meter reader to every installation involves the maintenance of a workforce and associated support equipment such as vehicles. Significant cost savings thus stand to be gained by the Utility company by the automation of the process of retrieving meter readings at periodic intervals and the consequent elimination of the workforce needed for this purpose.

2) Further, even more cost savings could be realized by the Utility company if the process of sending bills out to consumer, and collecting payment is also automated.

3) At the same time, the consumer stands to gain significant convenience as well if the process of sending to the Utility company can be completed by, for example, direct debiting from his bank account or online bill payment using a credit card.

Several arrangements have thus been proposed to gain these advantages. U.S. Pat. No. 3,747,068, issued to Bruner, et al., incorporated herein for reference, discloses a remote meter reading comprising means of reading and storing Utility usage information and transmitting this information using a transponder. In this arrangement, the meter would be interrogated by a mobile van containing a transmitter, thus providing for remote readout of the meter.

U.S. Pat. No. 4,315,251, issued to Robinson, et al., incorporated herein for reference, discloses an arrangement whereby the usage information is transmitted over the power line to a central location. Another example of a similar arrangement providing automatic meter reading over the power distribution lines can be found in U.S. Pat. No. 4,904,995, issued to Bonner et al., and incorporated herein for reference.

Yet another arrangement for automatic meter reading found in prior art is to provide for transmission of usage information over telephone lines. In this arrangement, the meter device is provided with an interface to a telephone line and initiates a telephone call to a central location at periodic intervals and communicates the usage information. Examples of such arrangements can be found in U.S. Pat. No. 4,8866,761, issued to Thornborough, et al., U.S. Pat. No. 4,817,131 issued to Thornborough, et al., U.S. Pat. No. 5,590,179, issued to Shincovich et al., and U.S. Pat. No. 5,852,658, issued to Knight, et al., all incorporated herein for reference.

A further arrangement for automated reading is disclosed in an article in the St. Louis Business Journal dated Dec. 9, 1996, entitled, “Automatic meters to help Union Electric go wireless” and available at the Web site http://www.bizjournals.com/stlouis/stories/1996/12/09/focus5.html. In this arrangement, the meter device is provided with the capability of communicating the usage information to a central location over a cellular communication network.

It will be seen that all these arrangements suffer from two serious disadvantages:

1) First, the means of communicating the usage information entails significant additional cost to the Utility company, as explained below.

The use of transponders communicating to mobile vans, while eliminating manual reading of the meter, still requires that the cans be driven to all locations. Meter reading is thus only partially automated in this case and still requires the maintenance of a significant workforce and vehicles.

The use of the power distribution lines for communicating of meter data, while allowing for complete automation of meter reading, requires the installation and maintenance of additional equipment in the form of a communications hub to handle this communication. In addition, the use of the power distribution lines for communication of meter data is not suited for the Gas and Water Utilities.

Similarly, the use of a special cellular network requires the installation and maintenance of base stations at significant expense.

The use of telephone lines for the purpose of communicating usage data entails the maintenance of separate leased lines by the Utility company at extra expense for this purpose. This is because the consumer cannot be expected to tolerate the tying up of his own telephone line by the automated meter device at arbitrary times that are not under his control.

2) Second, automation of the process of billing and payment is not possible in these arrangements. Three of the four events in the aforementioned cycle are thus left unattended and the aforementioned cost benefit to the Utility company and the convenience to the consumer of automating these events are not realized.

With respect to this second point of automating billing and payment, U.S. Pat. No. 4,803,632, issued to Frew, et al., incorporated herein for reference, discloses a somewhat better arrangement whereby the meter unit displays the usage information and allows the consumer to pay his bill by credit card. However, the means of communicating the usage and billing information is over the power distribution lines, thus entailing significant additional communication cost as mentioned above. In addition, the use of the power distribution lines for display of meter data is not suited for the Gas and Water Utilities. A further example of automated billing and payment, in additional to automated meter reading, can be found in U.S. Pat. No. 4,811,011, issued to Sollinger, incorporated herein for reference. Sollinger discloses an arrangement consisting of a microcomputer continually monitoring the meter and a main computer capable of polling this microcomputer over a communication link and retrieving the usage information. Sollinger further discloses an arrangement wherein the main computer is connected to bank computer permitting automatic debiting of consumer accounts. While this arrangement does provide for the automation of billing and payment, the communication link between the main computer and the microcomputer disclosed by Sollinger is either the power distribution line or the telephone line. Thus, the aforementioned disadvantages hold for Sollinger's disclosure as well.

Moreover, there exists an even further significant disadvantage suffered by all of the arrangements mentioned above. While all of the above arrangements provide for automated meter reading and even automated billing and payment to varying degrees and at some extra cost, detailed information regarding the usage pattern itself is not provided to the consumer. It is now well recognized, and also due to the deregulation of the Utility industry that there is significant interest in providing the consumer with this information to enable him to better manage Utility usage and thus save on Utility bills. Thus, it is seen from the Topical Summary Report of the Gas Research Institute, dated April 1995, that most Utility companies now strongly desire the means to provide their customers with such information in order to provide better service and to maintain a competitive edge. Therefore, it is no longer sufficient to simply automate the meter-reading and billing process. Adding value by presenting the consumer with usage data has, in fact, become a requirement. Thus, such systems such as those detailed above, which gather usage data but require further effort on the part of the Utility company, and thus added cost, to present all such information to the consumer fail to provide this added value.

U.S. Pat. No. 5,669,276, issued to Roos, incorporated herein for reference, addresses this problem. Roos discloses an arrangement whereby a Utility meter interface apparatus, which a meter and a computer located in the housing of the apparatus, is provided to connect between the Utility company and the user's structure. The computer is provided with interfaces to communication networks and is capable of communicating usage data to the Utility company as well as providing the consumer with usage information and controlling devices withing the user's structure to minimize Utility usage costs to the consumer. Thus, the disclosure by Roos not only automates meter-reading, billing and payment but also provides for Utility usage management. However, the incorporation of the computer within the meter apparatus makes this disclosure impractical to implement. It would be extremely expensive for the Utility company to install such an apparatus at every consumer site. Further, since many consumers already possess a personal computer connected to an information network such as the Internet, as seen from the results of a study by Strategis Group reported in the Network World, dated Mar. 22, 2000 and available at the Web site http://www.networkworld.com/news/2000/0322strategis.html?nf. indicating that 47% of American homes possess Internet access as of 1999, the provision of a meter apparatus containing a computer, as disclosed by Roos, is quite unnecessary and a wasteful expenditure for the Utility company.

Thus, in summary, it is seen that prior art does not teach a system which:

a) automates all four steps of Utility meter-reading, billing, payment and collection,

b) performs this automation at only a small additional expense, and

c) is capable of presenting the consumer with usage information in order to enable between usage management without additional effort from the Utility company.

### SUMMARY OF THE INVENTION

This invention describes a system which completely automates and integrates the functions of meter-reading, billing, payment and collection without entailing additional cost of communication to the Utility company. The system is also capable of presenting the consumer with detailed usage information without any extra effort on the part of the Utility company. The system is further capable of managing multiple Utility-consuming devices within the user's structure as well as procuring Utility services from multiple Utility companies so that Utility cost to the consumer is minimized.

### DESCRIPTION OF THE DRAWINGS

FIG. 1 is a schematic diagram of the first embodiment of the invention showing the components of the system.

FIG. 2a shows the operation of the meter device in the absence of external requests and commands.

FIG. 2b shows the sequence of operation performed at the end of a billing period.

FIG. 2c shows the sequence operations performed when a consumer retrieves the usage data.

FIG. 3 is a schematic diagram of the second embodiment of the invention showing the components of the system.

FIG. 4 shows the operation of the invention according to the third embodiment, where the system chooses the Utility company with the lowest rates.

FIG. 5 is a schematic diagram of the network of multiple meter devices described in the fourth embodiment.

### DETAILED DESCRIPTION OF THE PREFERRED EMBODIMENTS

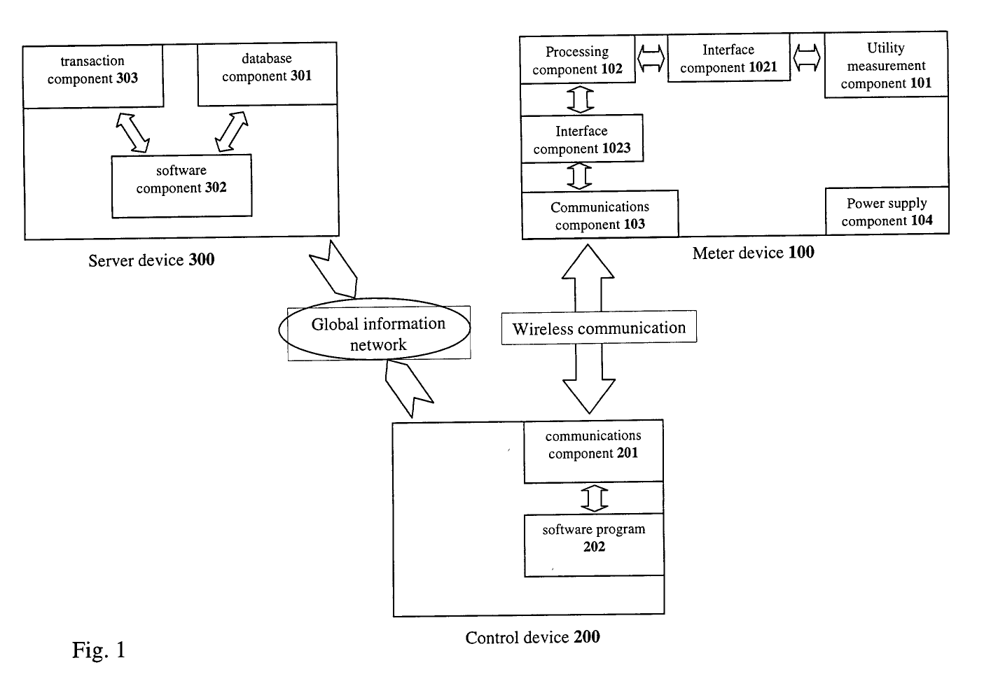

A first embodiment of the invention is shown schematically in FIG. 1. It is seen that the system comprises a meter device 100, a consumer control device 200, and a server device 300. The meter device is composed of a Utility measurement component 102 and the Utility measurement component 101, a communications component 103, an interface component 1023 between the processing component 102 and the communications component 103, and a power supply component 104. The Utility measured may, for example, be electricity, gas, water or steam. The means by which the Utility measurement component 101, measures the consumption of the Utility are standard and are well known in the art. The processing component 102 contains a microprocessor unit, a storage facility in the form of, for example, solid state, non-volatile memory and the software that enables the microprocessor unit to perform various functions. The interface component 1021 converts the reading of the measurement component 101 into digital format and thus enables the processing component 102 to obtain and store this reading. The communications component 103 is capable of radio communications over a short range of, for example, 100 meters. The interface component 1023 enables the processing component 102 to drive 3 the communications component 103 thus enabling the transmittal and receipt of information over a wireless communications medium. The power supply component 104 supplies power to the meter device 100 and consists of a battery and may include a further regulator element to convert alternating current (AC) to direct current (DC). Such regulators which convert AC to DC are well known in the art.

The consumer control device 200 may, for example, be a personal computer or a set-top box capable of communicating over a global information network such as, for example, the Internet, and a further communications component 201 capable of radio communications over a short range of, for example, 100 meters. In addition to the communication component 201, the consumer control device 200 includes additional hardware (not shown) and software (not shown) necessary for functioning as a personal computer or as an Internet appliance. Such hardware and software is well known in the art and consists of elements such as power supplies, microprocessors, memory, video interface circuits, monitors, storage components such as hard disks, modems, operating system software including device drivers and graphical user interface software. In addition, the consumer control device 200 is further provided with software program 202 which is capable of a) driving communications component 201 in order to conduct two-way wireless communications with the meter device 100, b) driving modems either directly or indirectly through services provided by the operating system in order to conduct two-way communications with the server device 300 over a global information network, such as the Internet, and c) presenting a graphical interface to the user in order to present various information to the user and to receive user input.

The server device 300 may, for example, be a server computer. Such server computers are well known in the art. The server device 300 is capable of communicating over a global information network such as, for example, the Internet, and is provided with a database component 301, a software component 302, and a transaction component 303. In addition to these components, the server device 300 includes additional hardware (not shown) and software (not shown) necessary for functioning as a server computer. Such hardware and software is well known in the art and consists of elements such as power supplies, microprocessors, memory, video interface circuits, monitors, storage components such as hard disks, modems, operating software including device drivers and graphical user interface software. The database component 301 contains information such as consumer account information, Utility usage data and billing rates, and provides an interface for the storage and retrieval of such information. The software component 302 is capable of conducting two-way communications with the consumer control device 200 over a global interface network such as the Internet, and of accessing the database component 301 for the storage and retrieval of various information. The server device 300 is further capable of authenticating and performing credit card transactions and direct debiting of bank accounts through the transaction component 303.

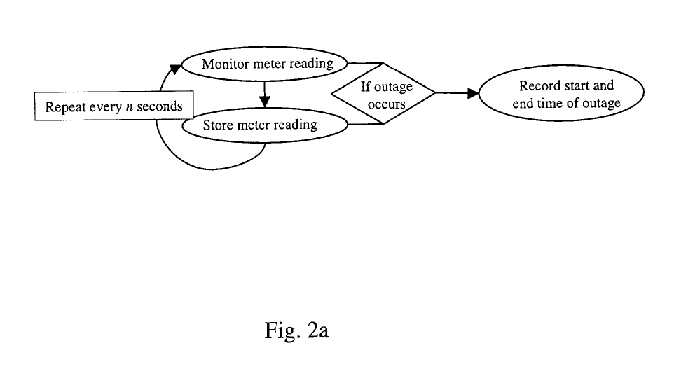

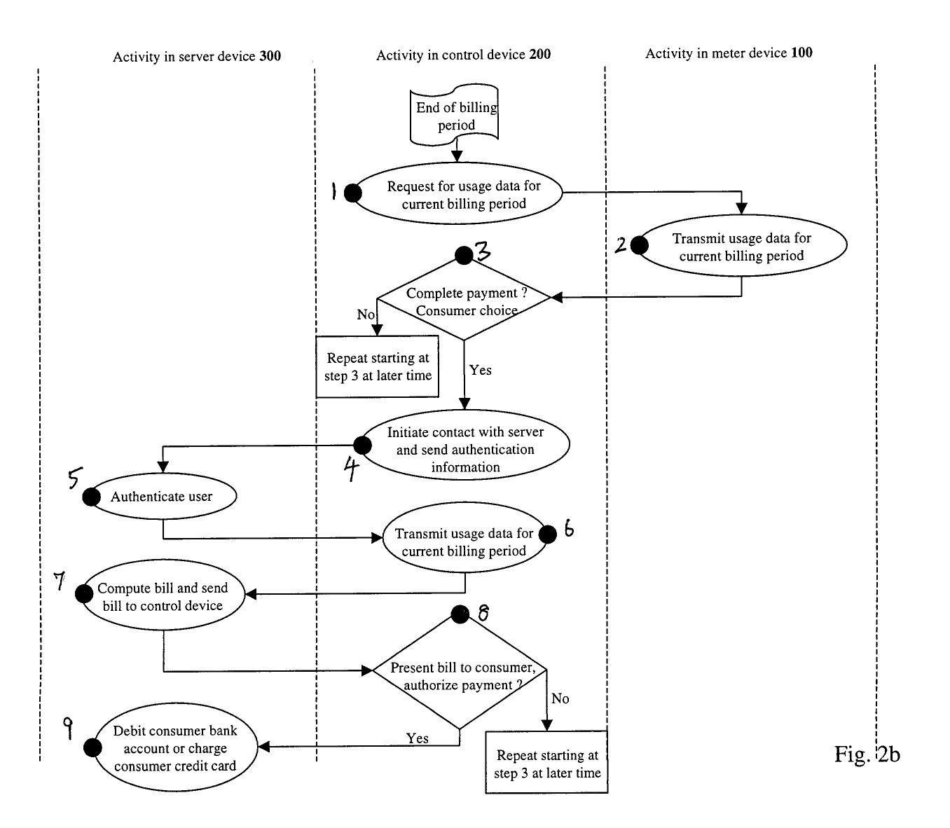

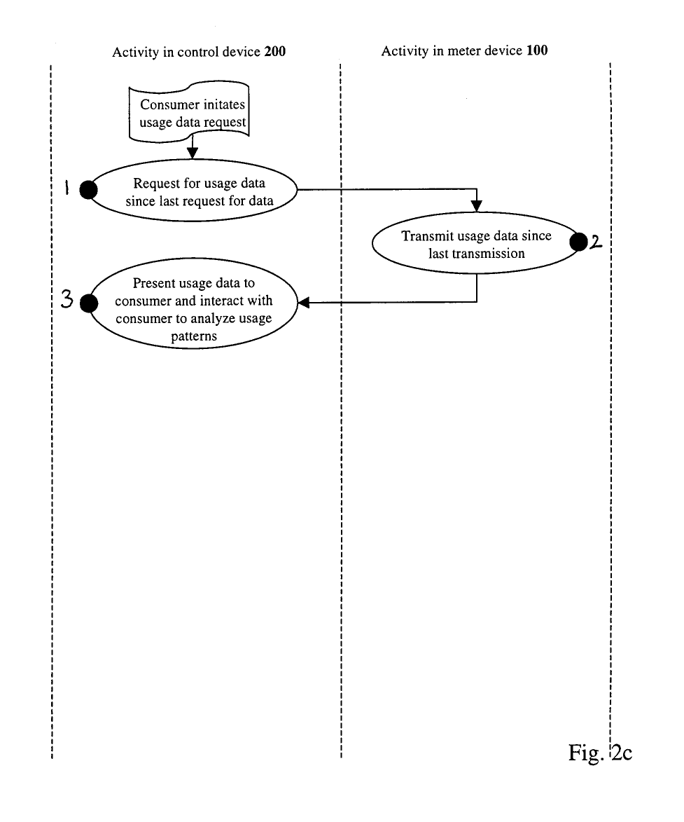

The method of operation of the system is now described with reference to FIG. 2. In FIG. 2a, the operation of the meter device 100 in the absence of external requests and commands is shown. In this mode of operation the meter device 100 simply monitors and stores the meter reading and the time of measurement every n seconds. The number n, may, for example, be in the range from 5 to 3600. Further, it should be noted that the number n is programmable by issuing appropriate commands to the processing component 102 through the communications component 103 over the wireless communication medium. Moreover, in this mode of operation, the meter device 100 further records information such as the start of a power outage duration and the end of such duration.

At the end of a billing period, which may, for example, be a month, as shown in FIG. 2b, the software program 202 in the consumer control device 200, requests and receives all usage data from the meter device 100 for the current billing period. The communication of both the request and the response occur over a wireless communication medium. The usage data may be transmitted in encrypted form in this step to ensure security. The software program 202 in the consumer control device 200 then presents the consumer with the choice of completing payment or delaying payment until a later time. Upon receipt of consumer confirmation that payment should be completed, the software program 202 initiates a two-way communication with the server device 300 over the global information network. Authentication of the consumer to the server device 300 is then performed using an encrypted password. Authentication of the consumer to the server device 300 is then performed using an encrypted password. Subsequently, the software program 202 transmits all usage data for the current billing period for the server device 300, where the bill is computed according to current rates and transmitted back to the consumer control device 200, where it is presented to the consumer. The consumer is then asked to authorize payment. Upon receipt of the authorization from the consumer, the software program 202 in the consumer control device 200 sends the authorization back to the server device 300 where the actual financial transaction is performed through the transaction component 303 by charging a credit card account of the consumer or by direct debiting of a consumer's bank account.

In this whole sequence operation, it should be noted that if the consumer chooses to postpone payment, either when presented with the choice as in step 3 or step 8 in FIG. 2b, the software program 202 simply aborts the payment but stores the meter reading obtained in steps 1 and 2 in a storage device in the consumer control device 200 which may, for example, be the hard disk or a nonvolatile memory device. Until payment for the billing period in question is completed, the software program 202 reminds the consumer periodically. This reminder consists of repeating the sequence of steps shown in FIG. 2 starting at step 3. Steps 1 and 2 need not be performed since the meter reading for the billing period in question has already been obtained. It should be further noted that the software program 202 can be constructed such that the consumer is informed specifically of a deadline date by which payment for the uncompleted billing period is due and beyond which late fees may be assessed. When the consumer does choose to complete payment, the software component 302 in the server device 300, in conjunction with the database component 301 can judge whether the payment is occurring beyond the deadline for the current billing period during step 7 in FIG. 2b. If the deadline has indeed passed, a late fee is added to the bill. The bill presented to consumer in step 8 will then reflect this addition of the late fee and the consumer will be informed of this addition in step 8.

It must be further noted that even though the deadline date for the next billing period and the late fee beyond that date are stored in the consumer control device 200 in, for example, a hard disk or a nonvolatile memory device in order to start the sequence of steps shown in FIG. 2b, this information is programable. For example, during one payment transaction shown in FIG. 2b, a further step (not shown in FIG. 2b) involving the server device 300 sending information to consumer control device 200 regarding the next deadline date and the late fee to be assessed beyond that date can be added. The software component 202 can then store this information in the consumer control device 200 in, for example, a hard disk or a nonvolatile memory device. It is thus possible in the present invention to dynamically change the deadline date as well as the late fee.

On the other hand, it should be noted that although the operation of the system described above details a method where the retrieval of usage data from the memory device 100 is initiated by the software program 202 in the consumer control device 200 at the end of a billing period, the system described herein is not limited in its operation by this method. The software program 202 could easily include the functionality to provide the consumer the freedom to perform bill payment as and when he desires. If the consumer chooses to pay for consumption of the utility from the time of the last bill at any time before the end of a billing period, he is free to initiate the sequence of events outlined in FIG. 2b. The system described herein thus make it possible for the Utility company to easily grant the consumer the freedom to choose his own billing cycles and even to change the choice as and when he desires while at the same time imposing time limits on the maximum length of a billing period. It is emphasized that this freedom of the consumer to initiate meter-reading and payment and the flexibility endowed by such freedom is a fundamental feature of the present invention that is not present in any of the other systems taught in the prior art.

Moreover, the system described in this embodiment can also be used by the consumer, as shown in FIG. 2c, to retrieve the usage data whenever he wants in order to simply monitor usage. In this context, it is easy to design the software program 202 to present such usage information to the consumer in an easily understood graphical manner and to provide such functions as, for example, plotting of usage by time of day or by day of week or presenting hologram plots over the past several months. Such functions enable the consumer to analyze his usage patterns and thus optimize his usage so that the bills are reduced. It is even possible for the software program 202 to include such functionality as to analyze the consumer's usage pattern and to present the consumer with tips to minimize his utility bills. It is important to note that the system described in the present invention thus makes all usage data available to the consumer without any effort at all from the Utility company. This ease of availability cannot be matched by any of the other systems described in prior art.

In addition, it must be emphasized the system described in this invention is eminently suited for automating the meter-reading, billing, payment and collection sequence for water and gas utilities in addition to electricity. It is not possible, for instance, to use the scheme described in prior art of communicating meter data over the power distribution line for water and gas meters. While it may be possible to employ the schemes described in the prior art that use telephone lines or cellular networks to communicate gas and water meter data, the expense incurred in the case of the cellular network and the need for installation of wires up to the water and gas meters (which are typically located far from wiring) in the case of telephone lines makes these systems unattractive. It is obvious that the invention described herein avoids these disadvantages by communicating the meter data through a control device and over a global information network, connection to which the consumer already possesses. Moreover, from the standpoint of the consumer convenience, the invention described herein provides the further advantage of integrating the billing and payment of electric, gas and water utilities within a single system. It must also be noted that in the system described in this embodiment it is also possible to upgrade the software embedded in the processing component 102 or the software program 202 remotely from the server device 300. This upgrade can be accomplished at any time the sequence of events described in FIG. 2b, which must be carried out every billing period is performed by means of an extra upload step (not shown in FIG. 2b) and can be entirely transparent to consumer. Such remote upgrading is advantageous since it provides the means to upgrade the software program 202 and/or the processing component 102 to newer versions which might fix bugs in the old versions or provide added functionality without requiring a visit from personnel to perform the upgrade. It is also possible by means of this remote upgrading facility to change parameters such as the frequency of recording of usage data in the processing component 102.

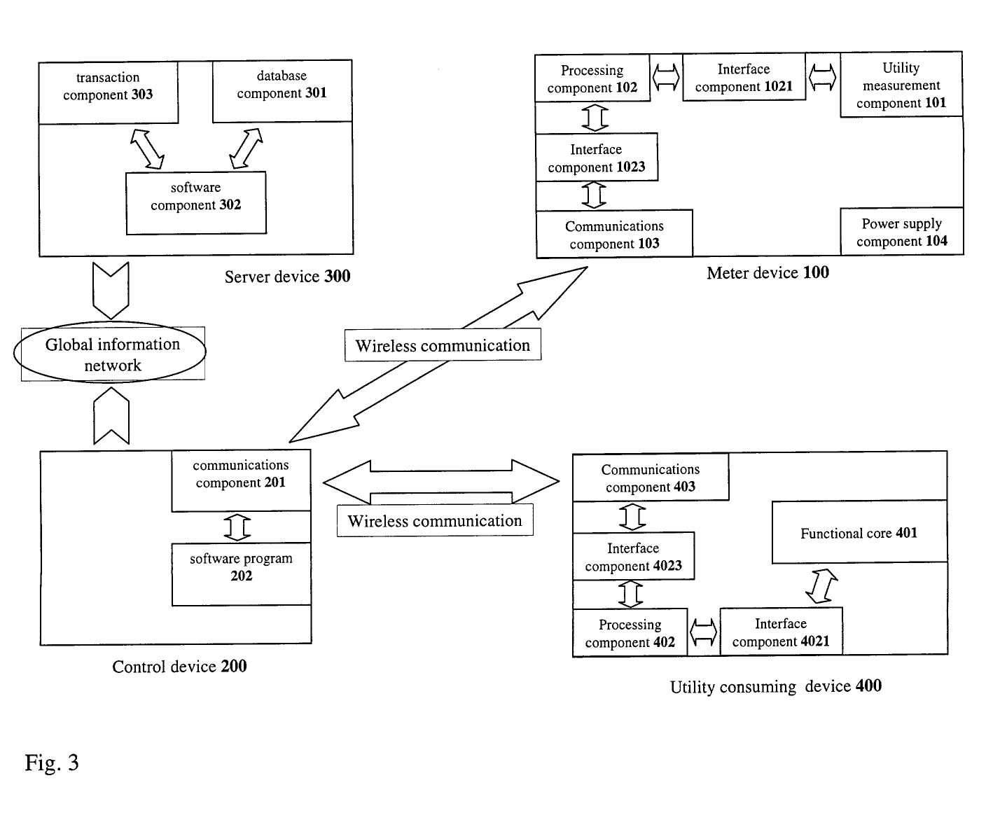

A second embodiment which extends the aforementioned first embodiment is now described with reference to FIG. 3. In this embodiment, a plurality of Utility-consuming devices 400 such as home electric appliances, gas stoves, etc., one example of which is shown in FIG. 3, are all provided with communication components 403 capable of radio communications over a short range of, for example, 100 meters. Each of the devices 400 is further provided with processing components 402, interface components 4032 between the processing components 402 and the communication components 403 and interface components 4021 between the processing components 402 and the actual functional core 401 in the consumer control device 200 to control the operation of Utility-consuming devices 400 such that the cost Utility usage is minimized. This is accomplished by the software program 202 obtaining time-of-day-dependent billing rates from the server device 300 and operating the devices 400 at precisely such times when the rates are low. Devices such as dishwashers, washing machines and heaters can be operated in this fashion. It is thus seen that the present invention can easily become a Utility usage management system without the addition of any extra hardware at all. This added functionality provides further value to the user.

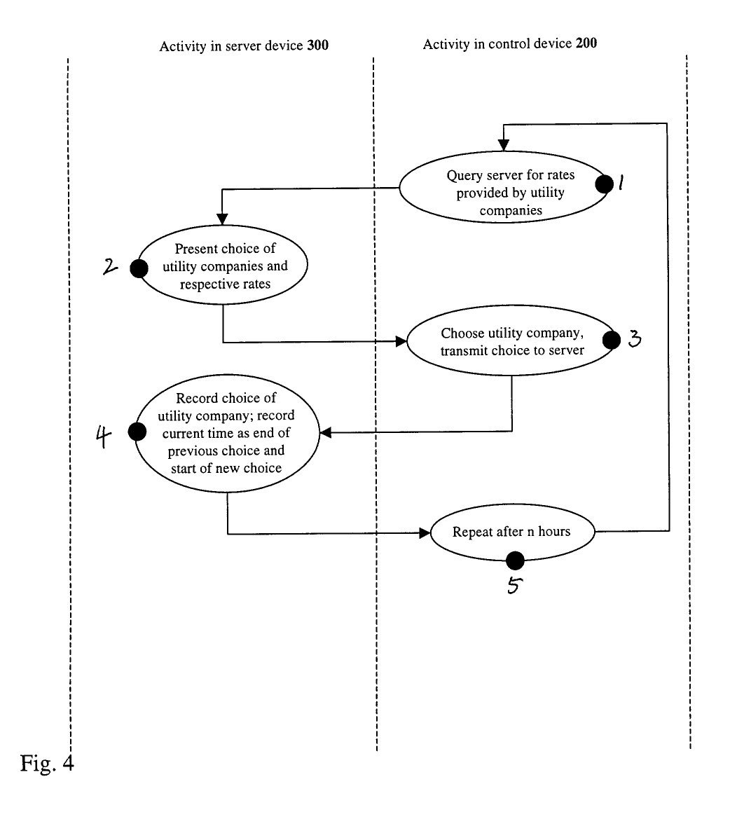

A third embodiment of the present invention is now described (FIG. 4). If it is possible for the consumer to buy Utility services from various companies, as is increasingly becoming the case in the current deregulated marketplace, the server device 300 could store information regarding current rates offered by multiple Utility companies. The software program 202 could then be provided with the functionality to query the server device 300 continually to pick and choose the Utility company which provides the lowest rates and buy services from that company. Additional modifications, changes, extensions, variations and other uses and applications will readily occur to those skilled in the art. For example, the meter device 100 could be made capable of detecting and recording attempts at tampering with the housing of the meter device and subsequently transmitting such attempts along with the usage data.

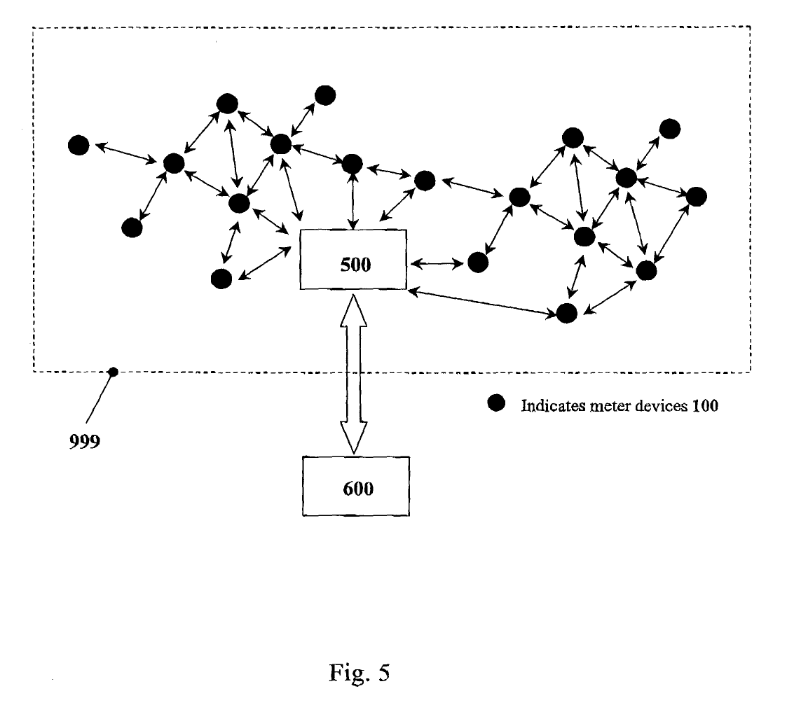

A fourth embodiment of the present invention is now described with reference to FIG. 5. As described earlier in the first embodiment, the communications components in the present invention are limited to short range. This range may, for example, be between 100 meters and 2 kilometers. The use of short-range wireless communications is one of the key aspects of the present invention. This is the reason why the present invention is superior to other wireless solutions that communicate over a long range. In the first and second embodiments of the invention, it was shown how the present invention provides means for a server device, located farther from the Utility consuming and metering devices, to communicate with metering devices through the use of a consumer control device located within physical wireless communication range to the Utility consuming and metering devices. In this fourth embodiment, this concept of using short-range wireless communications is further extended to eliminate even the use of a consumer control device located within physical wireless communication range to the Utility consuming and metering devices.

As shown in FIG. 5, the system consists of multiple meter devices 100, spread over a large geographical area 999 which may, for example, be 50 square miles. The meter devices 100 are, as in the first embodiment, capable of short-range wireless communications over a range of, for example, between 100 meters and 2 kilometers. The Utility measured by the meter devices 100 may be electricity, gas, water or steam. The system further consists of a gateway device 500 located within the geographical area 999. The gateway device 500 is capable of short-range wireless communications similar to the meter devices and is also connected to a server device 600 through a global communication network such as, for example, the Internet or through a public communication network, such as the telephone network.

As can be seen from this conceptual description of the system, not all meter devices are in direct communication range of the gateway device. However, if the system is deployed in such a manner that any meter device is within physical communication range of at least one other meter device, then it is possible for all meter devices 100 to communicate with gateway device 500 and vice versa. This is because the meter devices 100 form a network through which messages can be routed. Thus, as can be shown from FIG. 5, a message from any particular meter device is first transmitted to another meter device which is within communication range, which in turn, relays the message to another meter device and so on until it reaches the gateway device. Similarly, it is possible for the gateway device to send a message to any particular meter device even if it is not within direct physical communication range using this means of relaying the message through other meter devices. Since the gateway device is, in turn, connected to the server device, data from all meter devices can be accessed by the server device; further, messages can be sent from the server device to any meter device.

In this way, it is seen that the present invention provides a means of monitoring the Utility consumption at multiple meter devices spread over a large geographical area even though each meter device is only provided with the ability to communicate over a short-range, thus making the invention very cost-effective. It should also be noted that although this embodiment refers only to meter devices, it is easy to add other Utility-consuming devices such as home electric appliances, HVAC equipment, etc. to the same network as shown in FIG. 5, thus monitoring and controlling all devices using the same network.

In summary, it is thus seen that the entire sequence of meter-reading, billing, payment and collection is completely automated, thus providing all benefits outlined earlier. Further, by using a personal computer or an Internet appliance that the consumer already possesses, the present invention eliminates the need for the Utility company to provide expensive additional hardware. Moreover, by using a global information network such as the Internet for the transmission of the information, additional communication cost to the Utility company is avoided. In particular, it is noted that the system described in this invention is especially advantageous in that the same system can be used for electric, gas and water utilities. In addition, even if the connection to the Internet is performed over a telephone line, as is normal practice, it is seen that the consumer is fully in control of when he performs the communication, thus eliminating concerns regarding the tying up of telephone lines at arbitrary times when the consumer might want to use the line for his own purpose and therefore avoiding the need for a leased telephone line. It is also seen that it is easily possible for the Utility company to grant the consumer the freedom to choose his own billing cycles. Finally, all usage data is fully available to the consumer without any effort at all from the Utility company, offering the consumer added value in the form of usage monitoring and optimization.

While the foregoing embodiments have been described with reference to a home installation, it will readily be appreciated by one skilled in the art that the invention is applicable to businesses and other commercial structure. All such modifications, changes, extensions, variations and other uses and applications which do not depart from the spirit and scope of the invention are deemed to be covered by the invention which is limited only by the claims which follow.

What is claimed is:

1. A Utility meter-reading system comprising:
a plurality of meter devices spread over a geographical area, said meter devices capable of communicating with each other over a wireless communication link whose range is limited to less than the extent of the geographical area, said meter devices further capable of sensing usage of said Utility continually and recording said usage at periodic time intervals as usage data;
a control device located separately from said meter devices but within said geographical area, said control device capable of communicating with each of said plurality of meter devices either directly in the case where the meter device is physically located within communication range of said control device or indirectly in the case where the meter device is physically located beyond communication range of said control device through the means of using a chain of meter devices physically located within communication range of each other, the first meter device in the chain being physically located within communication range of control device, as message relays; and
a server device, capable of communicating with said control device over a global communications network.

2. The system recited in claim 1 wherein said meter devices are further capable of recording the start and end of durations of cessation of the provision of said Utility.

3. The system recited in claim 1 wherein said meter devices are further capable of recording time at which said recording of said usage is performed as part of said usage data.

4. The system recited in claim 1 wherein said Utility is electricity.

5. The system recited in claim 1 wherein said Utility is gas.

6. The system recited in claim 1 wherein said Utility is water.

7. The system recited in claim 1 wherein said Utility is steam.

8. A method of performing automated Utility meter-reading using the system recited in claim 1, wherein:
said control device requests and receives from each of said plurality of meter devices said usage data over a specific time period; and
said control device contacts said server device and transmits said usage data from each of said plurality of meter devices over said specific time period to said server device.

9. A method of performing automated Utility meter-reading using the system recited in claim 1, wherein:
said plurality of meter devices each transmits said usage data over a specific time period to said control device at periodic intervals; and
said control device contacts said server device and transmits such usage data from each of said plurality of meter devices over said specific time period to said server device.

10. The system recited in claim 1 further comprising a plurality of devices consuming said Utility, said devices capable of communicating with each other as well as with said meter device and said control device over a wireless communication medium.
